(19) United States
(12) Patent Application Publication
(10) Pub. No.: US 2008/0112511 A1
(43) Pub. Date: May 15, 2008

(54) Receiver

(76) Inventors: Steffen Paul, Baierbrunn (DE); Manfred Zimmermann, Sauerlach (DE); Clemens Buchacher, Bad Ischl (AU)

Correspondence Address: DICKSTEIN SHAPIRO LLP, 1177 AVENUE OF THE AMERICAS 6TH AVENUE, NEW YORK, NY, 10036-2714, US

(21) Appl. No.: 11/558,794

(22) Filed: Nov. 10, 2006

(51) Int. Cl. H03D 1/00; H04L 27/06

(52) U.S. Cl. 375/340; 375/232

(57) ABSTRACT

A receiver has a determination unit to determine a channel profile of received radio signals, the channel profile specifying the distribution of the received radio signals over a plurality of transmission paths, a selection unit to select sections of the channel profile, a calculation unit to calculate coefficients by using the selected sections of the channel profile, and an equalizer to equalize the received radio signals by using the calculated coefficients.

### TECHNICAL FIELD

This invention relates to receivers in general and more particularly to receivers receiving multi-path signals.

### BACKGROUND

In many mobile communications systems, such as the systems of the third mobile generation, particularly UMTS (universal mobile telecommunications system), code division multiple access (CDMA) is used as multiple access method. In CMDA, a plurality of subscribers occupies the same frequency band but the radio signal is coded differently for or by each subscriber, respectively. The different CDMA coding provides for subscriber separation. Coding is carried out by impressing a subscriber-specific CDMA spreading code on each data symbol of the digital data signal to be transmitted. The elements of the CDMA spreading code sequence used for this purpose are called chips, the symbol period being a multiple of the chip period.

After being radiated, a CDMA-coded transmitted signal is generally subject to multi-path propagation. Due to reflections, dispersion and diffraction of the transmitted radio signal at various obstacles in the propagation path, the transmitted signal reaches the receiver via a plurality of transmission paths and is differentially delayed by these transmission paths. A superimposition of differentially delayed signal components, so-called intersymbol interference (ISI), then occurs at the receiver end.

Due to multi-path propagation, the signal energy of a data symbol received at the receiver is distributed over several delay times. The time delay between two versions of the same transmitted signal can be up to 5 μs but can be also in the order of up to 20 μs. The existence of multi-path propagation may require special consideration when designing a wireless communication system.

There are at least two techniques to overcome the effects of multi-path propagation in high bandwidth systems, such as HSDPA (high speed downlink packet access), so that the original signal is restored with minimal distortion. One approach is the use of a rake receiver. A rake receiver comprises a plurality of so-called rake fingers. Each of the rake fingers is allocated to one of the transmission paths and thus receives the signal version transmitted via the respective transmission path. In each rake finger, the received signal may be despread with the spreading code at the chip clock rate. In this process, the received signal or, as an alternative, the spreading code is individually displaced in time for each rake finger in accordance with the time delay of the transmission path allocated to the rake finger. The despread signals of the individual rake fingers are then combined. For this purpose, a maximum ratio combiner (MRC) may be used. In the maximum ratio combiner, each of the despread signals is weighted at the symbol clock rate in accordance with the attenuation of the respective transmission paths and the weighted signals are subsequently superimposed.

Another approach to overcome the effects of multi-path propagation may include employing an adaptive equalizer. The equalizer may be implemented as a linear minimum mean square error (LMMSE) equalizer, which performs the task of recovering the transmitted signal by minimizing the mean squared error between the desired signal and an estimated version of the signal.

### BRIEF DESCRIPTION OF THE DRAWINGS

FIG. 1A schematically illustrates a wireless communication system.

FIG. 1B schematically illustrates how the channel response can be modeled with the aid of channel coefficients.

FIG. 2 schematically illustrates a channel profile.

FIG. 3 schematically illustrates a receiver 300 as an exemplary embodiment.

FIG. 4 schematically illustrates the distribution of the filter coefficients wᵢ over delay times τ.

FIG. 5 schematically illustrates an FIR filter 500 implemented as an equalizer.

FIG. 6 schematically illustrates a Wiener-Hopf equation and the reduction of the dimension of an autocorrelation matrix.

FIG. 7 schematically illustrates a receiver 700 as a further exemplary embodiment.

FIG. 8 schematically illustrates a receiver 800 as a further exemplary embodiment.

FIG. 9 schematically illustrates an FIR filter 900 combining an equalizer, one or more rake fingers and an MRC combiner.

FIG. 10 schematically illustrates an FIR filter 1000 combining an equalizer, one or more rake fingers and an MRC combiner.

FIG. 11 schematically illustrates a method 1100 as an exemplary embodiment.

FIG. 12 schematically illustrates a method 1200 as a further exemplary embodiment.

### DETAILED DESCRIPTION

One or more aspects and/or embodiments are described with reference to the drawings, wherein like reference numerals are generally utilized to refer to like elements throughout, and wherein the various structures are not necessarily drawn to scale. In the following description, for purposes of explanation, numerous specific details are set forth in order to provide a thorough understanding of one or more aspects of embodiments. It may be evident, however, to one skilled in the art that one or more aspects of the embodiments may be practiced with a lesser degree of these specific details. In other instances, known structures and devices are shown in block diagram form in order to facilitate describing one or more aspects of the embodiments. The following description is therefore not to be taken in a limiting sense, and the scope of the invention is defined by the appended claims.

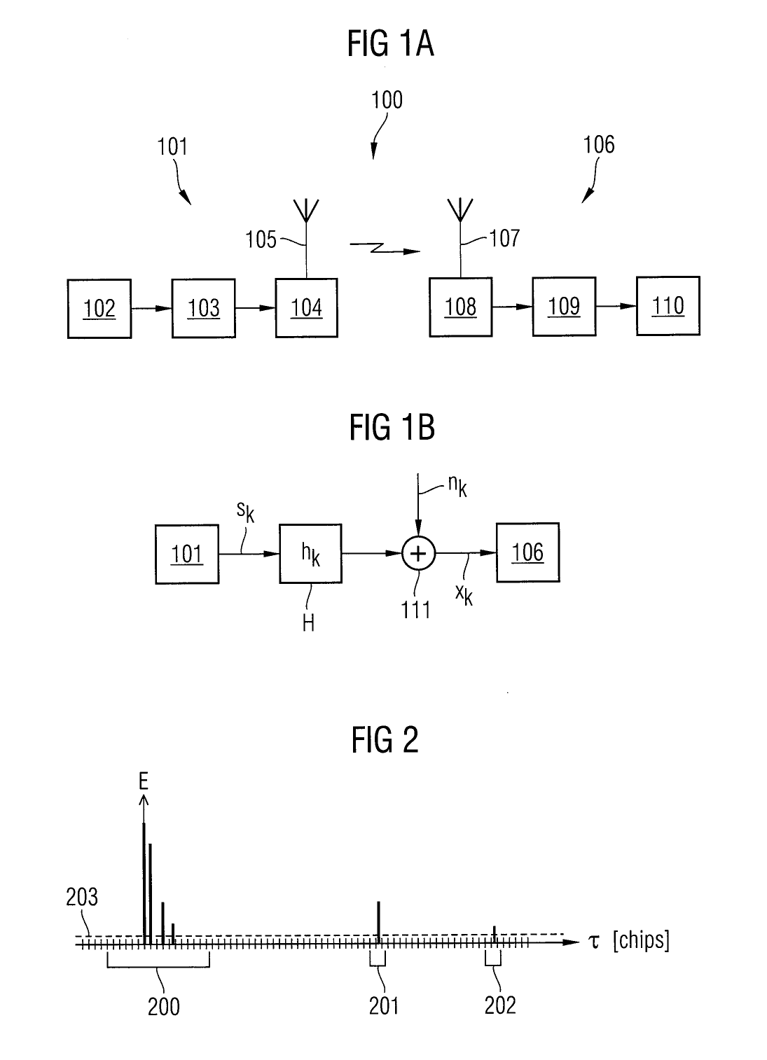

FIG. 1A shows a simplified block diagram of a wireless communication system 100. At a transmitter 101, data are sent from a data source 102 to a transmit data processor 103 that, for example, encodes and processes the data to generate analog signals. The analog signals are provided to a transmitter unit 104 that, for example, amplifies, filters and frequency up-converts the received analog signals to generate a signal suitable for transmission via one or more antennas 105 (only one is shown in FIG. 1A) to one or more receivers.

At a receiver 106, the transmitted signals are received by one or more antennas 107 and provided to a receiver unit 108. Within the receiver unit 108, each received signal is, for example, amplified, filtered, frequency down-converted and digitized. The digitized samples are provided to a receive data processor 109 that further processes and decodes the samples to recover the transmitted data. The decoded data are provided to a data sink 110.

During the transmission from the transmitter 101 to the receiver 106, the radio signals are subject to multi-path propagation due to reflections, dispersion and diffraction of the radio signals at various obstacles in the transmission path. The multi-path propagation between the transmitter 101 and the receiver 106 can be modeled as a transmission filter H with channel coefficients hₖ, as is illustrated in FIG. 1B. The transmitter 101 feeds transmission data or transmission symbols sₖ into the transmission channel, that is to say the transmission filter H. An additive noise signal nₖ can be taken into account by a model adder 111, and is added to the transmission symbols sₖ, which have been filtered with the channel coefficients hₖ, at the output of the transmission filter H.

The index k denotes the discrete time, represented by time steps. The transmission signals sₖ which have been filtered by the transmission filter H and on which noise is superimposed are received as receive signals xₖ by the receiver 106. In this case:

$${x}_{k} = {\sum }_{i = 0}^{L} {h}_{i} {s}_{k - i} + {n}_{k} \qquad ( 1 )$$

where L represents the order of the transmission channel that is modeled by the filter H. As can be seen from equation (1), intersymbol interference (ISI) is included because xₖ depends not only on sₖ but also on sₖ₋₁, . . . , s_{k-L}.

In FIG. 2 the effects of multi-path propagation are illustrated. The signals emitted from the transmitter 101 can follow different transmission paths to reach the receiver 106. This phenomenon creates a multi-path channel having a number of transmission paths with different time delays. A profile of such a channel is exemplarily shown in the diagram of FIG. 2 where the energy E of the signals received at the receiver 106 is plotted over the delay time τ. The delay time τ is expressed in units of chip durations. During a time interval 200 the diagram exhibits an accumulation of several energy peaks, and at later points in time 201 and 202 two more peaks occur. Each energy peak which appears in the channel profile of FIG. 2 can be associated with a transmission paths. The amplitude of each peak is a measure of the energy E transmitted over the respective transmission path. Thus, the signals represented by the first two peaks on the left hand side of the diagram were only slightly attenuated while transmitted via the respective transmission paths to the receiver 106, whereas all other transmission paths result in higher attenuation.

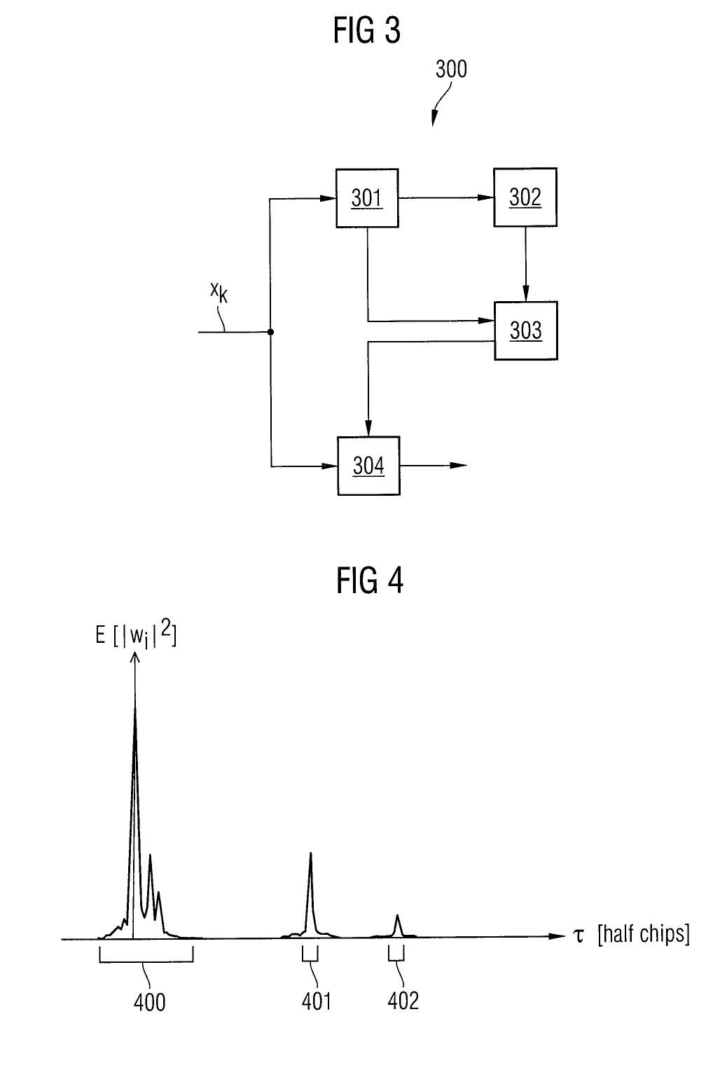

Referring to FIG. 3, a schematic block diagram of a receiver 300 is shown which serves as an exemplary embodiment of a first aspect. The receiver 300 may be implemented as the receiver 106 of the wireless communication system 100 shown in FIG. 1. The receiver 300 comprises a determination unit 301, a selection unit 302, a calculation unit 303 and an equalizer 304.

The determination unit 301 and the equalizer 304 have input terminals for receiving signals received by the receiver 300, respectively. The determination unit 301 is coupled to the selection unit 302 and the calculation unit 303 via input and output terminals, respectively. The selection unit 302 has an output terminal, which is connected to a control terminal of the calculation unit 303. An output terminal of the calculation unit 303 is connected to a control terminal of the equalizer 304. The equalizer 304 has an output terminal.

During the use of the receiver 300, the receiver 300 receives radio signals and may pre-process these signals, which is not shown in FIG. 3. The received signals, which may, for example, be digitized, are fed to the determination unit 301 and the equalizer 304 via their input terminals. The determination unit 301 determines a channel profile of the received radio signals, wherein the channel profile specifies the distribution of the received radio signals over a plurality of transmission paths. Depending on the distribution of the received radio signals over the transmission paths, the selection unit 302 selects sections of the channel profile. The calculation unit 303 calculates filter coefficients using the selected sections of the channel profile and provides the calculated filter coefficients to the equalizer 304. A filter comprised by the equalizer 304 uses the calculated filter coefficients to equalize the received radio signals. The equalized signals are outputted at the output terminal of the equalizer 304.

In the following the function of the receiver 300 is exemplarily explained in more detail with the aid of FIG. 2. As shown in the diagram of FIG. 2, the determination unit 301 determines the distribution of the energy of the received signals over the delay time τ. The selection unit 302 selects from the channel profile provided by the determination unit 301 those transmission paths which exhibit a significant path energy. According to one embodiment, transmission paths are selected, the energy of which exceeds a pre-determined threshold value 203. The selection unit 302 may not only select the delay times τ allocated to these transmission paths but time intervals 200, 201 and 202 surrounding the delay times τ allocated to the peaks of the energy rich transmission paths. When calculating the filter coefficients the calculation unit 302 only considers the selected time intervals 200, 201 and 202 and neglects the non-selected time intervals of the channel profile.

According to one embodiment, the equalizer 304 has the structure of a linear minimum mean square error (LMMSE) equalizer, which performs the task of recovering the transmitted signals sₖ by minimizing the mean squared error between a desired signal and an estimated version of the transmitted signal. For this purpose, the received signals xₖ are processed by a filter with a filter coefficient vector w. At the output of the filter an estimate ŝₖ of the transmitted signals sₖ is obtained. The difference between desired signals dₖ and the filter output ŝₖ is dₖ−ŝₖ. It is sought to minimize the mean squared error |dₖ−ŝₖ|². This leads to the Wiener-Hopf equation

Rₓₓ·w=r_{xd} (2)

where Rₓₓ is the autocorrelation matrix of the received signals xₖ and r_{xd} is the crosscorrelation vector between the desired signals dₖ and the received signals xₖ.

The solution for the filter coefficient vector w is

w=Rₓₓ⁻¹·r_{xd} (3)

If the noise power is sufficiently large, significant autocorrelation values are shifted to the main diagonal and the secondary diagonal of the autocorrelation matrix Rₓₓ. In this case the filter coefficient vector w is nearly proportional to the crosscorrelation vector r_{xd} and the crosscorrelation vector r_{xd} corresponds to the channel profile.

It was found that filter coefficients wᵢ having a significant amplitude occur at those delay times τ where the channel profile exhibits transmission paths having significant energies. A diagram illustrating the distribution of the filter coefficients wᵢ over the delay time τ is shown in FIG. 4. Time intervals 400, 401 and 402 shown in FIG. 4 correspond to the time intervals 200, 201 and 202 of FIG. 2, respectively.

If the architecture of an adaptive LMMSE equalizer is employed for the equalizer 304, the equalizer 304 includes an FIR (finite impulse response) filter, the basic structure of which is exemplarily shown in FIG. 5. The FIR filter 500 comprises delay elements 501, multipliers 502 and adders 503. The delay elements 501 are connected in series, and each delay element 501 is formed of a shift register delaying the input signals by one or more clock cycle periods. The multipliers 502 multiply the output signals of the delay elements 501 by corresponding complex conjugated filter coefficients w*₁. The adders 503 add the output signals of preceding adders 503 with the output signals of corresponding multipliers 502 to transmit the addition result to succeeding adders 503. As to “z⁻ⁿ” of the delay elements 501, the exponent indicates the amount of delay.

As can be seen from equation (3), computing the filter coefficients wᵢ for the FIR filter 500 requires computing the inverse of the autocorrelation matrix Rₓₓ. This arithmetic operation has a high complexity which increases cubically with the length L of the FIR filter 500. By using only selected time intervals 200, 201 and 203 of the channel profile for the calculation of the filter coefficients wᵢ the complexity of the autocorrelation matrix Rₓₓ and thus the computational effort to invert the autocorrelation matrix Rₓₓ can be reduced.

Using only the selected time intervals 200, 201 and 202 for calculating the filter coefficients wᵢ means that the filter coefficients wᵢ for the delay times which are not selected are set to zero. Therefore the delay elements 501, the multipliers 502 and the adders 503 corresponding to non-selected sections of the channel profile can be omitted. In other words, the length of the FIR filter 500 can be reduced and the delay times of some of the delay elements 501 must be configured correspondingly in order to take non-selected delay time intervals into consideration. Using the filter 500 is, for example, advantageous in case of long channel lengths, for example, in the range from 5 μs to 20 μs.

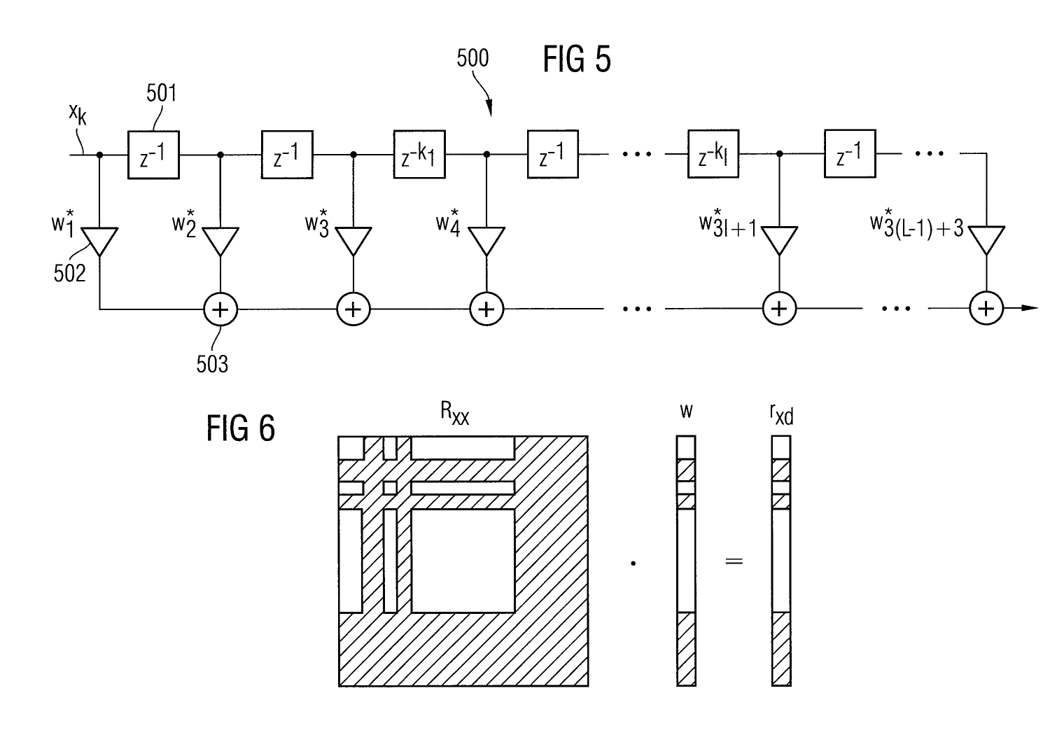

In the following, the advantages of selecting certain sections of the channel profile for calculating the filter coefficients wᵢ is explained by way of the exemplary channel profile shown in FIG. 2. The channel shown in FIG. 2 has a length of about 15 μs, which corresponds to an autocorrelation matrix Rₓₓ, of dimension 120×120 if the chip rate is 3.84 MHz and a twofold oversampling rate is used. When selecting the time intervals 200, 201 and 202 only 40 sampled data values are considered, which reduces the autocorrelation matrix Rₓₓ to a dimension of 40×40. FIG. 6 schematically illustrates the Wiener-Hopf equation of the present example. The hatched rows and columns of the autocorrelation matrix Rₓₓ mark the non-selected sections of the channel profile, which are not relevant for calculating the filter coefficients wᵢ. Omitting these matrix elements leads to an irregular structure of the autocorrelation matrix Rₓₓ and the autocorrelation matrix Rₓₓ to lose its Toeplitz structure. However, due to the reduced complexity of the autocorrelation matrix Rₓₓ its inversion requires only about a ninth of the computational effort compared to the inversion of an autocorrelation matrix Rₓₓ of dimension 120×120.

The algorithm for calculating the filter coefficients wᵢ can be implemented in software form to be embedded in a general-purpose signal processing chip. A computationally faster alternative would be to implement it in a special-purpose chip.

According to one embodiment, data transmission between the transmitter and the receiver 300 is based on the UMTS standard.

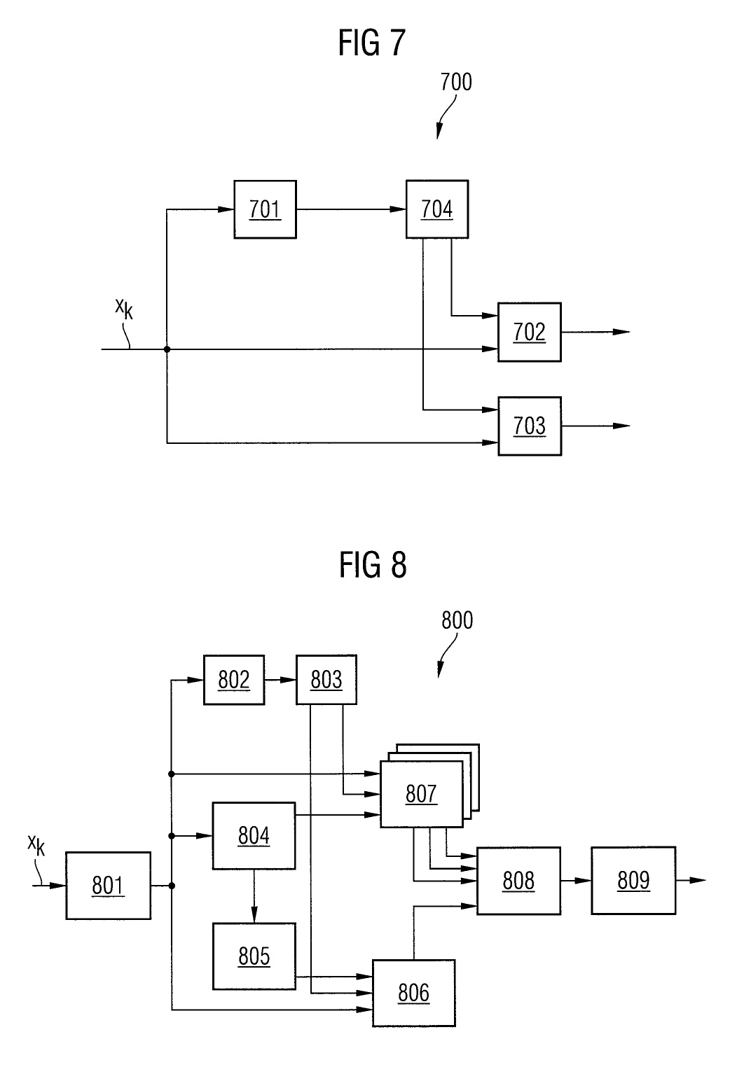

Referring to FIG. 7, a schematic block diagram of a receiver 700 is shown which serves as an exemplary embodiment of a second aspect. The receiver 700 may be implemented as receiver 106 in the wireless communication system 100 shown in FIG. 1. The receiver 700 comprises a determination unit 701, an equalizer 702, at least one rake finger 703 and a control unit 704.

The determination unit 701, the equalizer 702 and the at least one rake finger 703 have input terminals for receiving signals received by the receiver 700, respectively. The determination unit 701 is coupled to the control unit 704, and the control unit 704 feeds control terminals of the equalizer 702 and the at least one rake finger 703, respectively. The equalizer 702 and the at least one rake finger 703 have an output terminal, respectively.

During the use of the receiver 700, the receiver 700 receives radio signals and may pre-process these signals, which is not shown in FIG. 7. The received signals, which may, for example, be digitized, are fed to the determination unit 701, the equalizer 702 and the at least one rake finger 703 via their input terminals. The determination unit 701 determines a channel profile of the received radio signals, wherein the channel profile specifies the distribution of the received radio signals over a plurality of transmission paths. Each of the transmission paths is associated with a delay time. Depending on the distribution of the received radio signals over the transmission paths, the control unit 704 places the equalizer 702 on first delay times and the at least one rake finger 703 on at least one second delay time.

In the following the function of the receiver 700 is exemplarily explained in more detail with the aid of FIG. 2. As shown in the diagram of FIG. 2, the determination unit 701 determines the distribution of the energy of the received signals over the delay time τ. The control unit 704 places the equalizer 702 and the at least one rake finger 703 on delay times which exhibit significant path energies. For example, the equalizer 702 is placed on the time interval 200 and the rake finger 703 is placed on the time interval 201. In case the receiver 700 includes two rake fingers 703, the second rake finger 703 may be placed on the time interval 202.

One advantage of the receiver 700 is that it combines the advantages of an equalizer with those of a rake receiver. Due to its complexity, an equalizer is usually employed for shorter channels having length up to 5 μs. A rake receiver is often employed when longer delay times occur between adjacent peaks in the channel profile. By combining an equalizer and a rake receiver, the receiver 700 takes advantage of the equalizer as well as the rake receiver. Exemplarily, this can be seen from FIG. 2. During time interval 200 signals transmitted over at least four different transmission paths are received by the receiver 700. In this case, when signals from several transmission paths are received within a relatively short time interval, it is advantageous to employ the equalizer 702 to restore the original signals. If, however, the time delay between adjacent peaks in the channel profile becomes larger, employing one or more rake fingers 703 for recovering the original signals is advantageous. Due to the function of the control unit 704, the receiver 700 is flexible enough to adapt to different channel profiles, which is especially advantageous in the case of long channel lengths.

According to one embodiment, the control unit 704 places the equalizer 702 on a time interval if the signal energy received during this time interval exceeds a pre-determined threshold or a pre-determined fraction of the totally received energy. If adjacent peaks of the channel profile are spaced far apart, for example more than 3 μs, it can also be provided that the equalizer 702 is not employed and only the rake fingers 703 are placed on the corresponding delay times.

Referring to FIG. 8, a schematic block diagram of a receiver 800 is shown which serves as a further exemplary embodiment of the second aspect. The receiver 800 comprises a root raised cosine filter 801, a determination unit 802, a control unit 803, a channel estimator 804, a calculation unit 805, an equalizer 806, a plurality of rake fingers 807, a combiner 808 and a despreader 809. The function and the arrangement of the determination unit 802, the control unit 803, the equalizer 806 and the rake fingers 807 correspond to the functions and the arrangement of the determination unit 701, the control unit 704, the equalizer 702 and the at least one rake finger 703 of the receiver 700, respectively.

The role of the root raised cosine filter 801 is to filter the signals received by the receiver 800. The task of the channel estimator 804 is to determine the channel coefficients from the received signals. For this purpose, for example, training sequences are transmitted from the transmitter to the receiver 800. The determination of the channel coefficients is performed by correlating the distorted training sequences with undistorted training sequences known at the receiver 800. The determined channel coefficients are fed to the calculation unit 805, which uses the channel coefficients to calculate the filter coefficients for the equalizer 806.

The output signals of the equalizer 806 and the rake fingers 807 are combined by the combiner 808. In other words, the equalizer 806 can also be considered as a rake finger, the output terminal of which is connected to an input terminal of the combiner 808. The despreader 809 despreads the output signals of the combiner 808.

According to one embodiment, a maximum ratio combining (MRC) algorithm is used for combining the signals. For this purpose, each output signal feeding the combiner 808 is weighted with a complex number and thereafter the weighted output signals are summed. The output signal of the equalizer 806 is weighted with its output signal-to-noise ratio SNR which may be determined by the Rayleigh quotient:

$$SNR = \frac{{w}^{H} \cdot {R}_{xx} \cdot w}{{‖ w ‖}^{2} \cdot {σ}_{n}^{2}} - 1 \qquad ( 4 )$$

where σₙ is the noise standard deviation.

According to one embodiment, before combining the output signals of the equalizer 806 and the rake fingers 807, the output signals are scaled. This may be necessary due to different amplification factors of the equalizer 806 and the rake fingers 807. One possibility is to scale the output signal of the equalizer 806 to the output power of the rake fingers 807. This leads to the following scale factor G for the equalizer 806:

$$G = \frac{\sqrt{{w}^{H} \cdot {r}_{xd}}}{{‖ w ‖}^{2} \cdot {σ}_{d}} - \frac{{σ}_{n}^{2}}{\sqrt{{w}^{H} \cdot {r}_{xd}}} \qquad ( 5 )$$

where σ_{d} is the standard deviation of the desired signal.

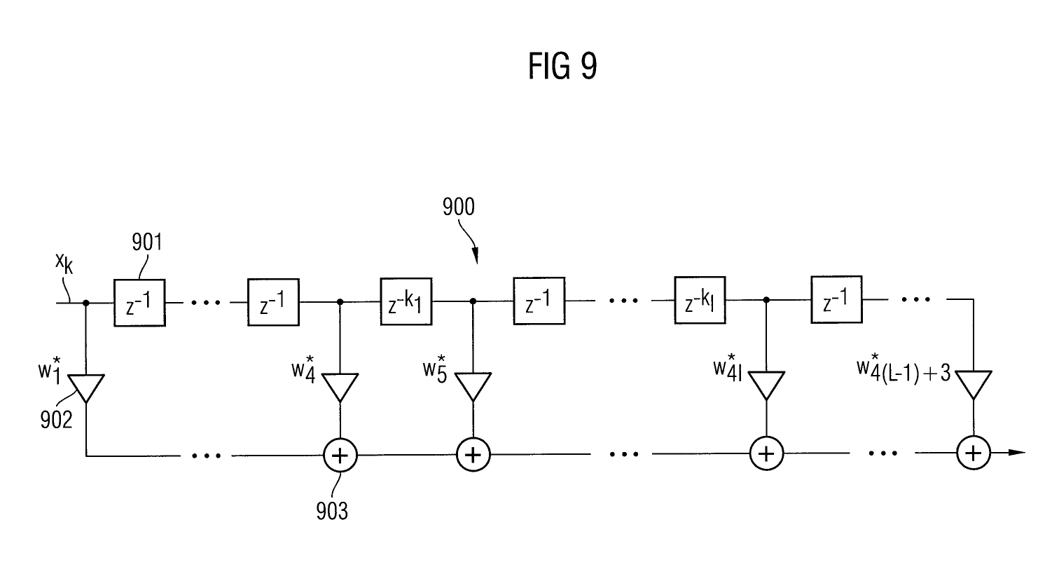

According to one embodiment, the equalizer 806 is an LMMSE equalizer comprising an FIR filter 900 which is exemplarily shown in FIG. 9. The FIR filter 900 includes delay elements 901 connected in series and each formed of a shift register delaying input signals by one or more clock cycle periods and multipliers 902 multiplying the output signals of the delay elements 901 by corresponding complex conjugated filter coefficients w*₁ and adders 903 for adding the output signals of preceding adders 903 with the output signals of corresponding multipliers 902 to transmit the addition result to succeeding adders 903. As to “z⁻ⁿ” of the delay elements 901, the exponent indicates the amount of delay.

According to a further embodiment, the rake fingers 807 are implemented in the FIR filter 900 together with the equalizer 806. For this, components of the FIR filter 900 are used as rake fingers 807. For one rake finger 807 a delay element 901, a multiplier 902 and an adder 903 is needed. The delay element 901 of a rake finger 807 has to be adjusted to the appropriate delay time (for example z^{-k}^{₁} in FIG. 9). In this case, the equalizer 806, the rake fingers 807 and the combiner 808 are implemented in the FIR filter 900. Despreading of the signals is carried out by the despreader 809. The output signal of the receiver 800 has the following structure:

$${\hat{y}}_{m} ( t ) = {\sum }_{n = 0}^{N - 1} {c}_{m , n} {\sum }_{l = 1}^{L} {w}_{4 l}^{*} \cdot x ( t - ( {n}_{l} - l ) \cdot T ) + {w}_{4 l + 1}^{*} \cdot x ( t - {n}_{l} \cdot T ) \qquad ( 6 )$$

where c_{m,n} is the spreading code of user m and T is the sampling time. Interpolation, phase correction and MRC weighting are performed with the aid of the coefficients w₄ₗ=τₗhₗ and w₄ₗ₊₁=(1−τₗ)hₗ. For a propagation path having the delay time τ′ₗ, it is defined τₗ:=τ′ₗ modulo T and nₗ is chosen that τ′ₗ=nₗ·T+τₗ.

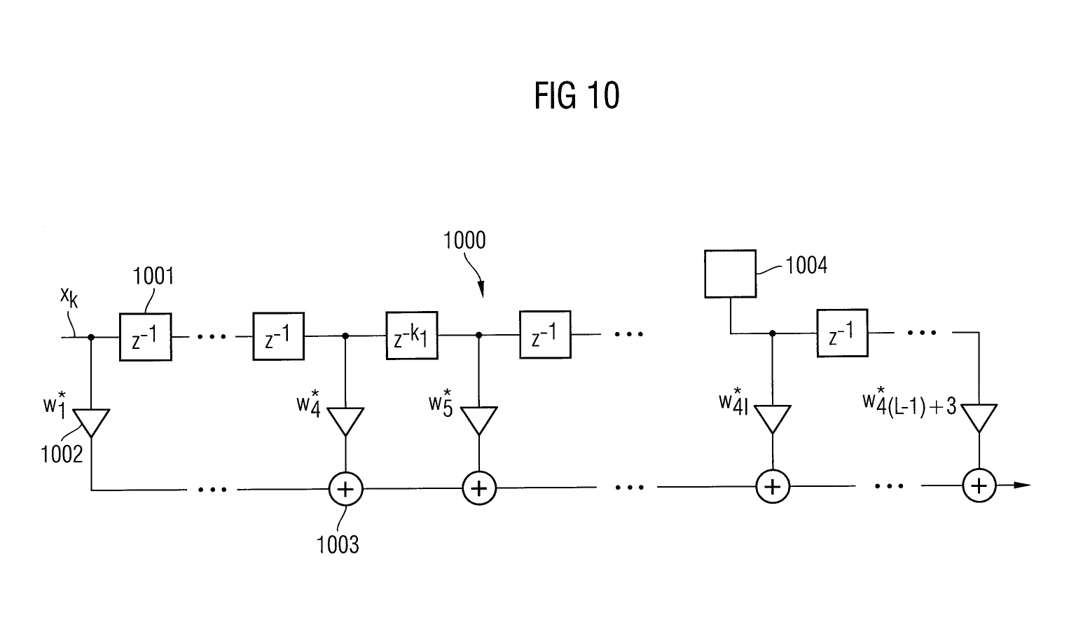

In FIG. 10 an FIR filter 1000 is shown which is similar to the FIR filter 900 of FIG. 9. The difference between the FIR filters 900 and 1000 is that in the FIR filter 1000 for implementing rake fingers the series connection of delay elements 1001 is interrupted and a buffer 1004 is used to set the appropriate delay time for a rake finger. Such a buffer 1004 feeding a part of the series connection of the delay elements 1001 is exemplarily shown in FIG. 10.

According to one embodiment, radio signal transmission between the transmitter and the receivers 700 and/or 800 are based on the UMTS standard and/or DS-CDMA (Direct-Sequence Code Division Multiple Access).

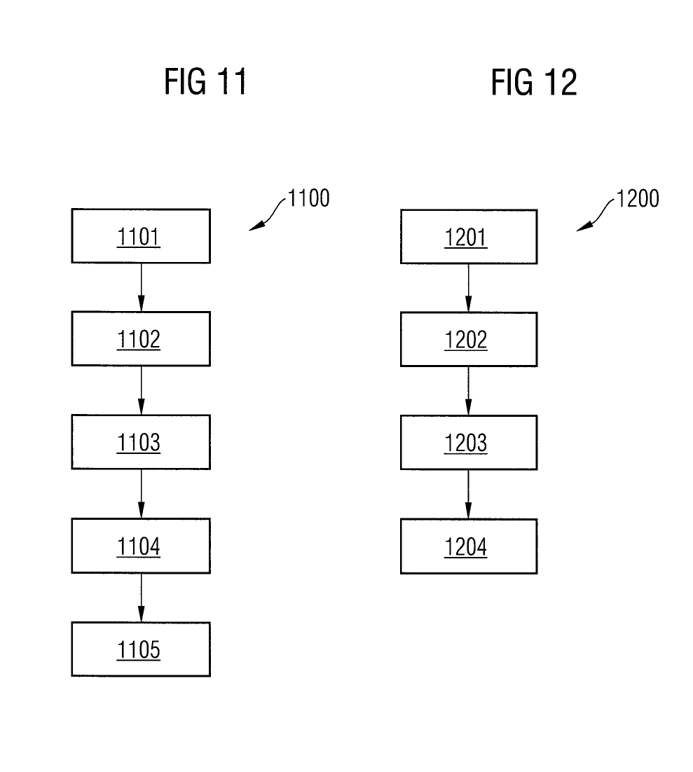

Referring to FIG. 11, a schematic flow diagram of a method 1100 is shown which serves as an exemplary embodiment of the first aspect. The method 1100 may be implemented in the receiver 106 of the wireless communication system 100 shown in FIG. 1. The method 1100 comprises steps 1101 to 1105. In step 1101 radio signals are received, the channel profile of which is determined in step 1102. The channel profile specifies the distribution of the received radio signals over a plurality of transmission paths. In step 1103 sections of the channel profile are selected in dependence on the distribution of the received radio signals over the plurality of transmission paths. The selected sections are used in step 1104 to calculate coefficients, which may be filter coefficients of a filter, for example an FIR filter. In step 1105 the received radio signals are equalized by using the calculated coefficients.

According to one embodiment, the selected sections are discontinuous from one selected section to the next selected section. For example the time intervals 200, 201 and 202 shown in FIG. 2 may be selected. In this case, the selected sections are delay time intervals 200, 201 and 202 allocated to transmission paths, the signal energy of which exceeds the predetermined threshold value 203. The time intervals between the selected time intervals 200, 201 and 202 of the channel profile are not used for calculating the filter coefficients. The filter coefficients associated with non-selected sections of the channel profile are set to predetermined values, for example to zero.

Referring to FIG. 12, a schematic flow diagram of a method 1200 is shown which serves as an exemplary embodiment of the second aspect. The method 1200 may be implemented in the receiver 106 of the wireless communication system 100 shown in FIG. 1. The method 1200 comprises steps 1201 to 1203. In step 1201 radio signals are received, the channel profile of which is determined in step 1202. The channel profile specifies the distribution of the received radio signals over a plurality of transmission paths. Each of the transmission paths is allocated to a delay time. In step 1203 an equalizer is placed on first delay times and at least one rake finger is placed on at least one second delay time.

According to one embodiment, the method 1200 comprises a step 1204, in which the output signals of the equalizer and the at least one rake finger are combined, for example by using MRC combining.

Referring to FIG. 2, the equalizer may be placed on the time interval 200 and the rake fingers may be placed on the time intervals 201 and 202. 36. The signal energy of the transmission paths allocated to the time intervals 200, 201 and 202 exceeds the predetermined threshold value 203.

In addition, while a particular feature or aspect of an embodiment may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise.” The terms “coupled” and “connected”, along with derivatives may have been used. It should be understood that these terms may have been used to indicate that two elements cooperate or interact with each other regardless whether they are in direct physical or electrical contact, or they are not in direct contact with each other. Furthermore, it should be understood that embodiments of the invention may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

What is claimed is:

1. A receiver comprising:
a determination unit to determine a channel profile of received radio signals, the channel profile specifying the distribution of the received radio signals over a plurality of transmission paths;
a selection unit to select sections of the channel profile;
a calculation unit to calculate coefficients by using the selected sections of the channel profile; and
an equalizer to equalize the received radio signals by using the calculated coefficients.

2. The receiver of claim 1, wherein selecting the sections of the channel profile depends on the distribution of the received radio signals over the plurality of transmission paths.

3. The receiver of claim 1, wherein the selected sections are discontinuous from one selected section to the next selected section.

4. The receiver of claim 1, wherein the channel profile specifies the distribution of the energy of the received signals over the plurality of transmission paths.

5. The receiver of claim 4, wherein the selected sections are delay time intervals allocated to transmission paths, the signal energy of which exceeds a predetermined threshold value.

6. The receiver of claim 1, wherein non-selected sections of the channel profile are not used for calculating the coefficients.

7. The receiver of claim 1, wherein the coefficients associated with non-selected sections of the channel profile are set to predetermined values.

8. The receiver of claim 1, wherein the coefficients are calculated with the aid of an autocorrelation matrix and all elements of the autocorrelation matrix are associated with selected sections of the channel profile.

9. The receiver of claim 1, wherein the equalizer comprises a filter and the coefficients are filter coefficients of the filter.

10. The receiver of claim 9, wherein the filter is an FIR filter.

11. A method comprising:
receiving radio signals;
determining a channel profile of the received radio signals, the channel profile specifying the distribution of the received radio signals over a plurality of transmission paths;
selecting sections of the channel profile;
calculating coefficients by using the selected sections of the channel profile; and
equalizing the received radio signals by using the calculated coefficients.

12. The method of claim 11, wherein selecting the sections of the channel profile depends on the distribution of the received radio signals over the plurality of transmission paths.

13. The method of claim 11, wherein the selected sections are discontinuous from one selected section to the next selected section.

14. The method of claim 11, wherein the channel profile specifies the distribution of the energy of the received signals over the plurality of transmission paths.

15. The method of claim 14, wherein the selected sections are delay time intervals allocated to transmission paths, the signal energy of which exceeds a predetermined threshold value.

16. The method of claim 11, wherein non-selected sections of the channel profile are not used for calculating the coefficients.

17. The method of claim 11, wherein the coefficients associated with non-selected sections of the channel profile are set to predetermined values.

18. The method of claim 11, wherein the coefficients are calculated with the aid of an autocorrelation matrix and all elements of the autocorrelation matrix are associated with selected sections of the channel profile.

19. The method of claim 11, wherein equalizing is carried out by filtering and the coefficients are used as filter coefficients.

20. The method of claim 19, wherein filtering is carried out by FIR filtering.

21. A receiver comprising:
a determination unit to determine a channel profile of received radio signals, the channel profile specifying the distribution of the received radio signals over a plurality of transmission paths and each of the transmission paths being allocated to a delay time;
an equalizer;
at least one rake finger; and
a control unit to place the equalizer on first delay times and to place the at least one rake finger on at least one second delay time.

22. The receiver of claim 21, further comprising:
a combiner to combine output signals of the equalizer and the at least one rake finger.

23. The receiver of claim 22, wherein the combiner is an MRC combiner.

24. The receiver of claim 21, wherein the first and second delay times are allocated to transmission paths, the signal energy of which exceeds a predetermined threshold value.

25. The receiver of claim 21, wherein the control unit places the equalizer on the first delay times if the signal energy received during the first delay times exceeds a predetermined portion of the totally received signal energy.

26. The receiver of claim 21, wherein the difference between any two of the first delay times is smaller than the difference between any of the first delay times and the at least one second delay time.

27. The receiver of claim 21, wherein the first delay times form a first delay time interval.

28. The receiver of claim 21, wherein the first delay times are different from the at least one second delay time.

29. The receiver of claim 21, wherein the equalizer comprises an FIR filter.

30. The receiver of claim 29, wherein the equalizer and the at least one rake finger are at least partially implemented within the FIR filter.

31. The receiver of claim 30, wherein the combiner is also at least partially implemented within the FIR filter.

32. The receiver of claim 29, wherein the FIR filter comprises delay elements and at least one buffer is coupled to at least one of the delay elements.

33. A method comprising:
receiving radio signals;
determining a channel profile of the received radio signals, the channel profile specifying the distribution of the received radio signals over a plurality of transmission paths and each of the transmission paths being allocated to a delay time; and
placing an equalizer on first delay times and placing at least one rake finger on at least one second delay time.

34. The method of claim 33, wherein output signals of the equalizer and the at least one rake finger are combined.

35. The method of claim 34, wherein combining is carried out by using MRC combining.

36. The method of claim 33, wherein the first and second delay times are allocated to transmission paths, the signal energy of which exceeds a predetermined threshold value.

37. The method of claim 33, wherein the equalizer is placed on the first delay times if the signal energy received during the first delay times exceeds a predetermined portion of the totally received signal energy.

38. The method of claim 33, wherein the difference between any two of the first delay times is smaller than the difference between any of the first delay times and the at least one second delay time.

39. The method of claim 33, wherein the first delay times form a first delay time interval.

40. The method of claim 33, wherein the first delay times are different from the at least one second delay time.

41. The method of claim 33, wherein the equalizer comprises an FIR filter.

42. The method of claim 41, wherein the equalizer and the at least one rake finger are at least partially implemented within the FIR filter.

43. A wireless communication system comprising a transmitter and the receiver of claim 1.

44. A wireless communication system comprising a transmitter and the receiver of claim 21.
